(19) United States
(12) Patent Application Publication
(10) Pub. No.: US 2014/0176022 A1
(43) Pub. Date: Jun. 26, 2014

(54) COMPLEX COMPOUNDS HAVING A POLYDENTATE, ASYMMETRICAL LIGAND AND THE USE THEREOF IN THE OPTO-ELECTRONIC FIELD

(71) Applicants: Lars Wesemann, Tubingen (DE); Hartmut Schubert, Bodelshausen (DE); Hermann August Mayer, Tubingen (DE); Harmut Yersin, Sinzing (DE); Andreas Rausch, Haiming (DE); Janet Arras, Voehringen (DE)

(72) Inventors: Lars Wesemann, Tubingen (DE); Hartmut Schubert, Bodelshausen (DE); Hermann August Mayer, Tubingen (DE); Harmut Yersin, Sinzing (DE); Andreas Rausch, Haiming (DE); Janet Arras, Voehringen (DE)

(73) Assignee: Merck Patent GmbH, Darmstadt (DE)

(21) Appl. No.: 14/234,710

(22) PCT Filed: Jul. 25, 2012
(86) PCT No.: PCT/EP2012/064631

§ 371 Date: Jan. 24, 2014

(30) Foreign Application Priority Data
Jul. 26, 2011 (DE) 10 2011 079 846.3

(51) Int. Cl. H01L 51/00

(52) U.S. Cl. CPC H01L 51/0091; H01L 51/009
USPC 315/363; 556/20; 252/301.16; 427/66

(57) ABSTRACT

The invention describes electronic devices comprising a metal complex compound having a first metallic centre M1 and a second metallic centre M2 and a polydentate, asymmetrical ligand L1, which contains a phosphido or amido donor D1 bridging the first and second metallic centres M1 and M2, and a further donor D2, which is bonded either to the first or to the second metallic centre, and uses of a complex of this type in the electronic field and for the generation of light, and to the production of devices of this type.

The present invention relates to electronic devices, such as organic electroluminescent devices (OLEDs), light-emitting electrochemical cells (LEECs), organic solar cells (OSCs), organic field-effect transistors and organic lasers, which comprise organotransition-metal complex compounds as light emitters and/or light absorbers. Some particularly suitable complex compounds and the use thereof in the opto-electronic field are described.

Organotransition-metal complex compounds are important building blocks for opto-electronic devices, such as organic solar cells or organic electroluminescent devices. This applies, in particular, to compounds which are able to function as triplet emitters. In the case of triplet emission, also known as phosphorescence, high internal quantum yields of up to 100% can be achieved if the singlet state, which is also excited and is energetically above the triplet state, is able to relax completely into the triplet state and radiation-free competing processes remain unimportant. However, many triplet emitters which are basically suitable for opto-electronic applications have the disadvantage of a long emission lifetime, which can result in a drop in efficiency, for example in OLED devices provided with emitters of this type.

Yersin et al. in WO 2010/006681 A1 have proposed organotransition-metal compounds which have a very small energetic separation ΔE between the lowest triplet state and the higher singlet state and in which efficient re-occupation from the efficiently occupied T₁ state into the S₁ state can therefore already occur at room temperature. This re-occupation opens a fast emission channel from the short-lived S₁ state, which enables the total emission lifetime to be significantly reduced. Complexes containing metal centres having a d⁸-electron configuration, i.e., in particular, based on the very expensive metals rhodium, iridium, palladium, platinum and gold, have been described as particularly suitable for this purpose.

The present invention was based on the object of providing organotransition-metal complex compounds based on readily available and very inexpensive transition metals which are ideally at least equal to the organotransition-metal complex compounds known from WO 2010/006681 in their physical properties, such as colour purity, emission decay time and quantum efficiency.

The present invention relates to the electronic device having the features of Claim 1. The present invention likewise relates to the processes having the features of Claims 13 to 15. Preferred embodiments of the device according to the invention are indicated in dependent Claims 2 to 12. The wording of all claims is hereby incorporated into this description by way of reference.

An electronic device according to the invention is distinguished by the fact that it comprises a polynuclear metal complex compound having a first metallic centre M¹ and a second metallic centre M² and a polydentate, asymmetrical ligand L¹, which contains a donor D¹ bridging the first and second metallic centres M¹ and M². The ligand L¹ furthermore contains a donor D², which is bonded either to the first or to the second metallic centre.

The ligand L¹ thus functions both as μ²-bridge ligand (for the first and second metallic centres) and also as chelating ligand (for the first or second metallic centre). The at least one further donor D² here is bonded only to one of the metallic centres M¹ or M², in no case to both, which is attributable, in particular, to the asymmetrical structure of the ligand. The ligand L¹ as a whole has neither point- nor mirror-symmetrical properties, in general it has a C₁ symmetry, which will also be illustrated with reference to the preferred embodiments described below.

The donor D¹ is either a phosphido or an amido donor, i.e. a donor containing a divalent nitrogen or a divalent phosphorus of the general formula PR₂⁻ (phosphido donor) and NR₂⁻ (amido donor), where R is preferably a C₁-C₄₀-hydrocarbon radical. These donors carry a negative charge, the term donor in the present case should therefore be understood primarily in the sense of “electron donor”.

Besides the donors D¹ and D², the ligand L¹ particularly preferably contains a further donor D³, which is bonded to the same metallic centre as the donor D².

The donors D² and D³ are very generally selected, independently of one another, from the group with R—NC, R—CN, RO⁻, RS⁻, RN═CR′, R₃N, and R₃P. In preferred embodiments, the donors D² and D³ are, in particular, in the form of a tertiary amine (R₃N) or a tertiary phosphine (R₃P), where here too R and R′ is preferably defined as C₁-C₄₀-hydrocarbon radical.

D² and/or D³ are particularly preferably part of an aromatic, heterocyclic system. Thus, for example, the nitrogen donor used can be an N ring atom of a corresponding nitrogen heterocycle.

D¹ and D² and/or D² and D³ are preferably linked to one another via a bridge fragment comprising at least two carbon atoms. One of these carbon atoms or even both may be part of an aromatic or non-aromatic ring system.

Correspondingly, the ligand L¹ particularly preferably has one of the formulae I to IX, in which the variables
D¹, D² and D³ are, independently of one another, a nitrogen or phosphorus atom,
F¹ and F⁵ are, independently of one another, an aryl, heteroaryl, cycloalkyl or heterocycloalkyl group,
F² to F⁴ and F⁶ are, independently of one another, a heteroaryl group containing N and/or P as hetero ring atom,
R is a C₁-C₄₀-hydrocarbon radical,
R¹, R², R⁵ and R⁶ are, independently of one another, hydrogen or a C₁-C₄₀-hydrocarbon radical if they are bonded to a nitrogen atom,
R¹, R², R⁵ and R⁶ are, independently of one another, a C₁-C₄₀-hydrocarbon radical if they are bonded to a phosphorus atom and
R³ and R⁴ are, independently of one another, hydrogen, halogen or a C₁-C₄₀-hydrocarbon radical, where n=an integer between 1 and 5:

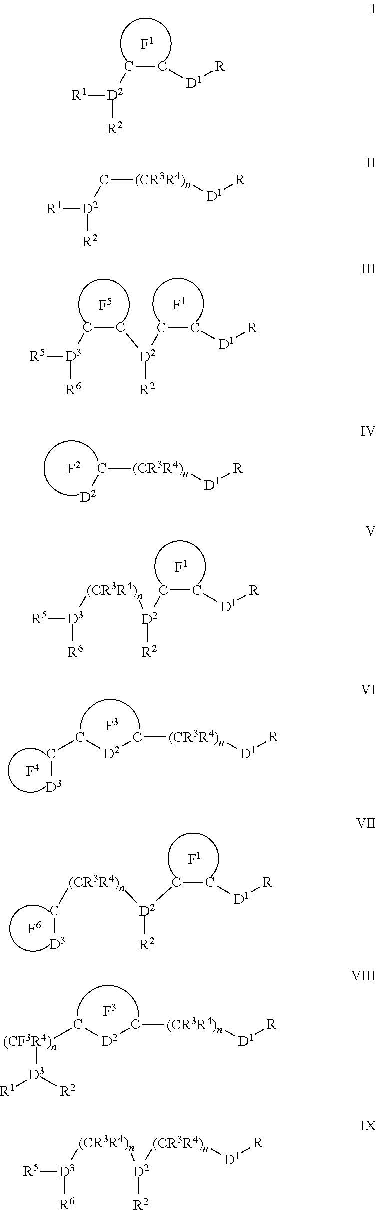

A C₁- to C₄₀-hydrocarbon radical, such as the radicals or fragments R, R¹ and R¹ to R⁶ mentioned, is for the purposes of the present description preferably an alkyl, cycloalkyl, alkenyl, cycloalkenyl, alkynyl, cycloalkynyl, alkylcycloalkyl, heteroalkyl, heterocycloalkyl, heteroalkylcycloalkyl, aryl, heteroaryl, aralkyl or heteroaralkyl radical. In preferred embodiments, each of these radicals/fragments may have one or more halogen, hydroxyl, thiol, carbonyl, keto, carboxyl, cyano, sulfone, nitro, amino and/or imino functions.

The expression alkyl radical or alkyl fragment relates, in particular, to a saturated, straight-chain or branched hydrocarbon group which has 1 to 20 carbon atoms, preferably 1 to 12 carbon atoms, particularly preferably 1 to 6 carbon atoms. Examples thereof are the methyl, ethyl, propyl, isopropyl, isobutyl, t-butyl, n-hexyl, 2,2-dimethylbutyl or n-octyl group.

The expressions alkenyl and alkynyl radical or fragment relate, in particular, to at least partially unsaturated, straight-chain or branched hydrocarbon groups or fragments which have 2 to 20 carbon atoms, preferably 2 to 12 carbon atoms, particularly preferably 2 to 6 carbon atoms. Examples thereof are the ethenyl, allyl, acetylenyl, propargyl, isoprenyl or hex-2-enyl group.

The expressions cycloalkyl, cycloalkenyl and cycloalkynyl radical relate, in particular, to saturated or partially unsaturated cyclic groups which have one or more rings which have, in particular, 3 to 14 ring carbon atoms, particularly preferably 3 to 10 ring carbon atoms. Examples thereof are the cyclopropyl, cyclohexyl, tetralin or cyclohex-2-enyl group.

The expression heteroalkyl radical relates, in particular, to an alkyl, an alkenyl or an alkynyl group in which one or more (preferably 1, 2 or 3) carbon atoms or CH or CH₂ groups have been replaced by an oxygen, nitrogen, phosphorus and/or sulfur atom. Examples thereof are alkyloxy groups, such as methoxy or ethoxy, or tertiary amine structures.

The expression heterocycloalkyl radical relates, in particular, to a cycloalkyl, cycloalkenyl or cycloalkynyl group in which one or more (preferably 1, 2 or 3) ring carbon atoms or ring CH or CH₂ groups have been replaced by an oxygen, nitrogen, phosphorus and/or sulfur atom, and can stand, for example, for the piperidine or N-phenylpiperazine group.

The expression aryl radical relates, in particular, to an aromatic group which has one or more rings which contain, in particular, 5 or 6 to 14 ring carbon atoms, particularly preferably 5 or 6 to 10 ring carbon atoms. Examples thereof are a phenyl, naphthyl or 4-hydroxyphenyl group.

The expression heteroaryl radical relates, in particular, to an aryl group in which one or more (preferably 1, 2 or 3) ring carbon atoms or ring CH or CH₂ groups have been replaced by an oxygen, nitrogen, phosphorus and/or sulfur atom. Examples thereof are the 4-pyridyl, 2-imidazolyl or the 3-pyrazolyl group.

The expressions aralkyl or heteroaralkyl radical relate, in particular, to groups which, in accordance with the above definitions, contain both aryl and/or heteroaryl groups and also alkyl, alkenyl, alkynyl or heteroalkyl groups. Examples thereof are arylalkyl, arylalkenyl, arylalkynyl, arylheteroalkyl, arylheteroalkenyl, arylheteroalkynyl, heteroarylheteroalkyl, heteroarylheteroalkenyl, heteroarylheteroalkynyl, arylcycloalkyl, heteroarylcycloalkyl, arylheterocycloalkyl, heteroarylheterocycloalkyl, heteroarylcycloalkenyl, arylcycloalkenyl, arylcycloalkynyl, heteroarylcycloalkynyl, arylheteroalkenyl, heteroarylheteroalkenyl, arylheteroalkynyl, heteroarylheteroalkynyl, heteroarylalkyl, heteroalkenyl and heteroarylalkynyl groups.

The expressions alkylcycloalkyl or heteroalkylcycloalkyl radical relate to groups which, in accordance with the above definitions, contain both cycloalkyl or heterocycloalkyl and also alkyl, alkenyl, alkynyl and/or heteroalkyl groups. Examples of such groups are alkylcycloalkyl, alkenylcycloalkyl, alkynylcycloalkyl, alkylheterocycloalkyl, alkenylheterocycloalkyl, alkynylheterocycloalkyl, heteroalkylcycloalkyl, heteroalkenylcycloalkyl, heteroalkylheterocycloalkyl, heteroalkenylheterocycloalkyl, heteroalkynylcycloalkyl, and heteroalkynylheterocycloalkyl groups.

In particularly preferred embodiments, the ligand L¹ has one of the following structures X to XVIII:

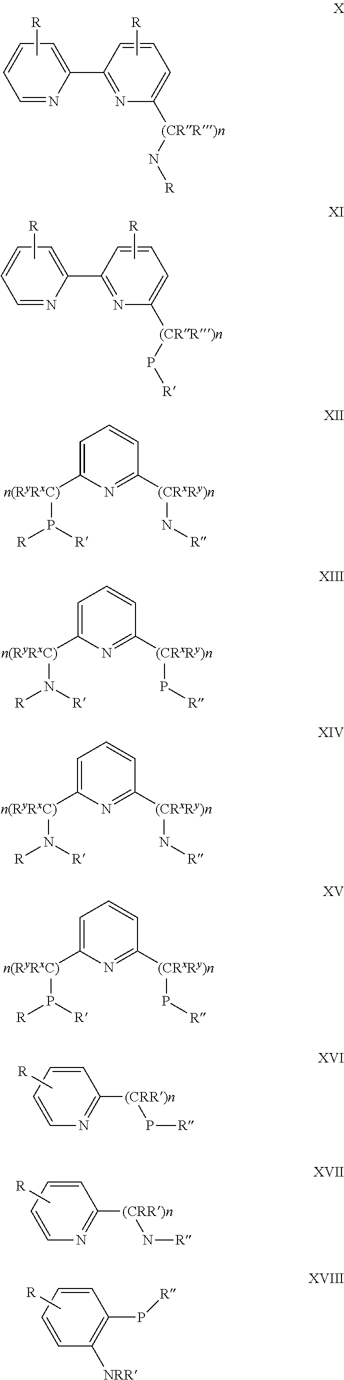

In these formula too, the variables R, R′, R″ and R′″ stand for the C₁- to C₄₀-hydrocarbon radical defined above. The variable n is preferably an integer between 1 and 5.

Metal complex compounds which are preferred in accordance with the invention may have further metallic centres besides the metallic centres M¹ and M². Especial preference is given here to metal complex compounds having two to eight metallic centres. All metallic centres are preferably ionised metal atoms.

The metallic centres M¹ and M² and, if present, further metallic centres are preferably selected, independently of one another, from the group with Cu, Ag, Au, Pd, Pt, Rh, Ir, Re, Os, Mo, W and Zn. Particular preference is given in accordance with the invention to homonuclear metal complex compounds, i.e. complex compounds in which all metallic centres consist of the same metal.

In particularly preferred embodiments, metal complex compounds which are preferred in accordance with the invention have one of the following formulae XIX or XX. In these formulae,
M¹ and M² are, independently of one another, Cu, Ag, Au, Pd, Pt, Rh, Ir, Re, Os, Mo, W or Zn,
the ligands L¹ shown diagrammatically containing the donors D¹ and D² as well as D¹ and D² and D³ are preferably ligands of the formulae I to XIX, and
L² and L³ are preferably non-bridging ligands.

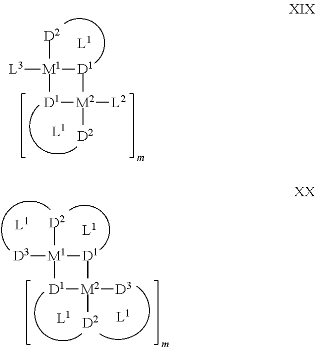

Non-bridging ligands are to be taken to mean ligands which do not bond simultaneously to two or more metal centres. Even though such ligands are not structure-forming, they may have a great influence on the separations between the metal centres of a polynuclear complex in that they increase or reduce the electron densities at the metal centres. The ligands are important for the saturation of the coordination sphere of the metal or for charge equalisation or for both. These ligands L¹ can therefore be neutral or anionic. Furthermore, the ligands L¹ can be monodentate or bidentate.

Neutral, monodentate ligands which are suitable as non-bridging ligands are preferably selected from the group with carbon monoxide, nitrogen monoxide, nitriles (RCN), isonitriles (RNC), such as, for example, t-butyl isonitrile, cyclohexyl isonitrile, adamantyl isonitrile, phenyl isonitrile, mesityl isonitrile and 2,6-dimethylphenyl isonitrile, ethers, such as, for example, dimethyl ether and diethyl ether, selenides, amines, such as, for example, trimethylamine, triethylamine and morpholine, imines (RN═CR′), phosphines, such as, for example, triphenylphosphine, phosphites, such as, for example, trimethyl phosphite, arsines, such as, for example, trifluoroarsine, trimethylarsine and triphenylarsine, stibines, such as, for example, trifluorostibine or triphenylstibine, and nitrogen-containing heterocycles, such as, for example, pyridine, pyridazine, pyrazine, pyrimidine and triazine.

Suitable anionic, monodentate ligands are preferably selected from the group with hydride, deuteride, the halides F, Cl, Br and I, azide, alkylacetylides, aryl- or heteroarylacetylides, alkyl, aryl and heteroaryl, as have been defined above, hydroxide, cyanide, cyanate, isocyanate, thiocyanate, isothiocyanate, aliphatic or aromatic alcoholates, such as, for example, methanolate, ethanolate, propanolate and phenolate, aliphatic or aromatic thioalcoholates, such as, for example, methanethiolate, ethanethiolate, propanethiolate and thiophenolate, amides, such as, for example, dimethylamide, diethylamide and morpholide, carboxylates, such as, for example, acetate, trifluoroacetate, propionate and benzoate, anionic, nitrogen-containing heterocycles, such as, for example, pyrrolide, imidazolide, pyrazolide, aliphatic and aromatic phosphides or aliphatic or aromatic selenides.

Suitable di- or trianionic ligands are, for example, O²⁻, S²⁻ or N³⁻.

Neutral or mono- or dianionic bidentate ligands which are suitable as non-bridging ligands are preferably selected from the group with diamines, such as, for example, ethylenediamine, N,N,N′,N′-tetramethylethylenediamine, propylenediamine, N,N,N′,N′-tetramethylpropylenediamine, cis- or trans-diaminocyclohexane, cis- or trans-N,N,N′,N′-tetramethyldiaminocyclohexane, imines, such as, for example, 2-[1-(phenylimino)ethyl]pyridine, 2-[1-(2-methylphenylimino)ethyl]pyridine or 2-[1-(ethylimino)ethyl]pyridine, diimines, such as, for example, 1,2-bis-(methylimino)ethane, 1,2-bis(ethylimino)ethane, 1,2-bis(isopropylimino)-ethane, 2,3-bis(methyl-imino)butane, 2,3-bis(isopropylimino)butane or 1,2-bis(2-methylphenylimino)ethane, heterocycles containing two nitrogen atoms, such as, for example, 2,2′-bipyridine or o-phenanthroline, diphosphines, such as, for example, bis(diphenylphosphino)methane, bis(diphenylphosphino)ethane, bis(dimethylphosphino)methane, bis(dimethylphosphino)ethane, bis(diethylphosphino)methane or bis(diethylphosphino)ethane, 1,3-diketonates derived from 1,3-diketones, such as, for example, acetylacetone, benzoylacetone, 1,5-diphenylacetylacetone, dibenzoylmethane and bis(1,1,1-trifluoroacetyl)methane, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, salicyliminates derived from salicylimines, such as, for example, methylsalicylimine, ethylsalicylimine, phenylsalicylimine, dialcoholates derived from dialcohols, such as, for example, ethylene glycol, 1,3-propylene glycol and dithiolates derived from dithiols, such as, for example, 1,2-ethylenedithiol and 1,3-propylenedithiol.

It is furthermore also possible to employ bidentate monoanionic ligands which, with the metal, have a cyclometallated five-membered ring or six-membered ring having at least one metal-carbon bond, in particular a cyclometallated five-membered ring. These are, in particular, ligands as are generally used in the area of phosphorescent metal complexes for organic electroluminescent devices, i.e. ligands of the phenylpyridine, naphthylpyridine, phenylquinoline, phenylisoquinoline, etc., type, each of which may be substituted or unsubstituted. A multiplicity of such ligands are known to the person skilled in the art in the area of phosphorescent electroluminescent devices, and he will be able to select further ligands of this type as non-bridging ligands without inventive step.

The polynuclear metal complex compound of a device according to the invention may also contain only a part-fragment of the structure XIX, namely the dinuclear structure containing M¹ and M² and the ligands L¹ and L², but without the ligands L² and/or L³. Instead of this, a copper halide (CuX where X═Cl, Br or I), for example, may be attached.

Furthermore, L² and L³ may also be part of a bridging ligand.

The metal complexes selected are particularly preferably organic transition-metal compounds which have a ΔE separation between the lowest triplet state and the higher singlet state of between 50 cm⁻¹ and 3000 cm⁻¹, i.e. have the same properties in this respect as the complexes described in WO 2010/006681. Regarding the calculation or measurement of the energy separation ΔE, reference is made to the statements in this respect in WO 2010/006681.

The device according to the invention is, in particular, a device from the group consisting of organic electroluminescent devices (OLEDs), light-emitting electrochemical cells (LEECs), organic solar cells (OSCs), organic field-effect transistors and organic lasers. Further fields of application which come into question are OLED sensors, in particular gas and vapour sensors which are not hermetically shielded from the outside.

In particular if the electronic device according to the invention is an organic electroluminescent device, it is preferred for the device to comprise the metal complex as constituent of an emitter layer. The proportion of the metal complex in the emitter layer is in this case preferably between 0.1 and 50% by weight.

As is known, OLEDs are built up from a plurality of layers. A layer-like anode, for example consisting of indium tin oxide (ITO), is usually located on a substrate, such as a glass sheet. A hole-transport layer (HTL) is arranged on this anode. A layer of PEDOT/PSS (poly(3,4-ethylenedioxythiophene)polystyrene sulfonate), which serves to lower the injection barrier for holes and prevents indium from diffusing into the junction, may optionally also be located between the anode and the hole-transport layer. The emitter layer, which in the present case comprises the metal complex described above having the asymmetrical ligand, is very generally applied to the hole-transport layer. Under certain circumstances, the emitter layer may also consist of this complex. Finally, an electron-transport layer (ETL) is applied to the emitter layer. A cathode layer, for example consisting of a metal or metal alloy, is in turn applied thereto by vapour deposition in a high vacuum. As protective layer and in order to reduce the injection barrier for electrons, a thin layer of lithium fluoride, caesium fluoride or silver may optionally also be applied between cathode and the ETL by vapour deposition.

In operation, the electrons (=negative charge) migrate from the cathode in the direction of the anode, which provides the holes (=positive charge). In the ideal case, holes and electrons meet in the emitter layer, which is why this is also called the recombination layer. Electrons and holes form a bonded state, which is called exciton. A metal complex compound, such as that described in the present case, can be excited by an exciton by energy transfer. This can be converted into the ground state and can emit a photon in the process. The colour of the emitted light depends on the energy separation between excited state and ground state and can be varied in a targeted manner by variation of the complex or complex ligands.

In particular if the device according to the invention is an organic solar cell, it is preferred for the device to comprise the metal complex as constituent of an absorber layer, where the proportion of the metal complex in the absorber layer is preferably between 30 and 100% by weight. An organic solar cell is a solar cell which consists at least predominantly of organic materials, i.e. of hydrocarbon compounds.

As in the case of OLEDs, two electrodes are also provided in organic solar cells. The absorber layer, in which the metal complex described in the present application is used, is arranged between these.

As already mentioned, the metal complex described in the present case can emit light. By variation of the ligands, the ΔE separation between the lowest triplet state the higher singlet state can be varied, so that it is in principle possible to set the wavelength of the emitted light to defined values, in particular also to very short-wave values, so that blue light is emitted. In particular with copper complexes which have the asymmetrical complex ligand described, excellent results have been achieved in this respect. Correspondingly, the present invention also encompasses a process for the generation of light of a certain wavelength or for the generation of blue emission, where in both cases the metal complex described having the asymmetrical ligand is provided and used.

The complex compounds described are generally very readily soluble in organic solvents, such as benzene or toluene. This opens up the possibility of printing basically any desired substrate with the complex compounds. Correspondingly, the present invention also relates to a process for the production of an electronic device as described above, in which the metal complex compound described having the asymmetrical ligand is printed onto a substrate.

Further features of the invention arise from the following description of preferred embodiments. It should be explicitly emphasised at this point that all optional aspects of the devices according to the invention or the processes according to the invention described in the present application can, in an embodiment of the invention, each be achieved individually or in combination with one or more of the further optional aspects described. The following description of preferred embodiments serves merely for explanation and for better understanding of the invention and should in no way be understood as restrictive.

### WORKING EXAMPLE 1

The ligand [o(Me₂N)(PhPH)C₆H₄] was reacted with one equivalent of the copper amide [CuN(CH₂)₄] in toluene. After about one hour, the reaction mixture was covered with a layer of hexane. It was possible to isolate the product complex [Cu₂{NH(CH₂)₄}₂{o(Me₂N)(PhP)C₆H₄}₂] having the formula

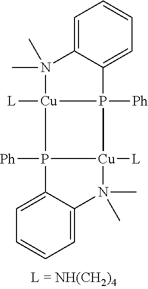

in crystalline form after several hours.

### WORKING EXAMPLE 2

Six equivalents of the ligand [o(Me₂N)(PhPH)C₆H₄] were reacted with six equivalents of the copper amide [CuN(CH₂)₄] or copper mesityl (CuMes) and one equivalent of copper halide in toluene. After about one hour, the reaction mixture was covered with a layer of hexane. It was possible to isolate a compound which exhibited intense red luminescence both in solution and also in the solid state. Crystals of the compound exhibit the composition [Cu-o(Me₂N)(PhP)C₆H₄]₆×Cu halide (halide=Br, Cl).

1-15. (canceled)

16. An electronic device comprising a polynuclear metal complex compound having a first metallic centre M¹ and a second metallic centre M² and a polydentate, asymmetrical ligand L¹, which contains a phosphido or amido donor D¹ bridging the first and second metallic centres M¹ and M², and a further donor D², which is bonded either to the first or to the second metallic centre.

17. The device according to claim 16, wherein the ligand L¹ contains a further donor D³, which is bonded to the same metallic centre as the donor D².

18. The device according to claim 16, wherein D² and D³ is independently of one another, R—NC, R—CN, RO⁻, RS⁻, RN═CR′, R₃N, and R₃P, where R and/or R¹ are a C₁-C₄₀-hydrocarbon radical.

19. The device according to claim 16, wherein D² and D³ is independently of one another, R₃N and/or RN═CR′ and/or R₃P, where R and/or R¹ are a C₁-C₄₀-hydrocarbon radical.

20. The device according to claim 16, wherein D¹ and D² and/or D² and D³ are linked to one another via a bridge fragment comprising at least two carbon atoms, which may optionally be part of an aromatic or non-aromatic ring system.

21. The device according to claim 16, wherein the ligand L¹ has one of the formulae I to IX 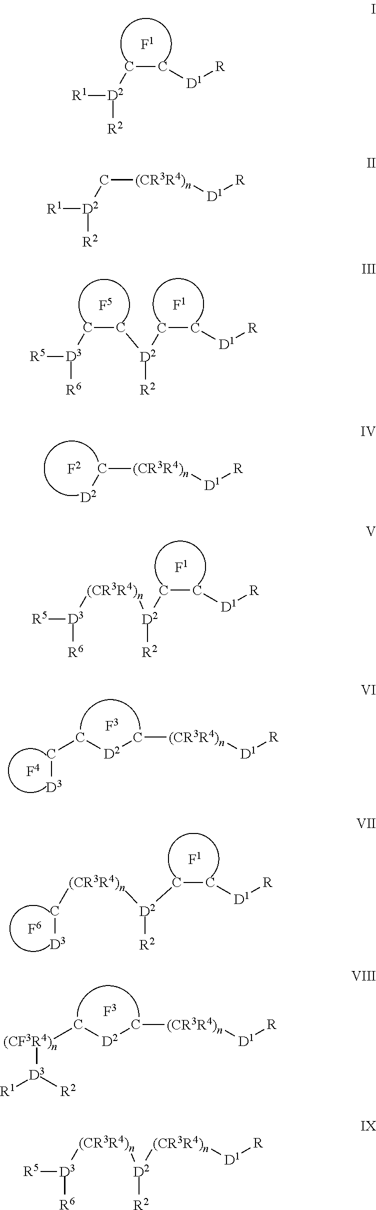
in which
D¹, D² and D³ are, independently of one another, a nitrogen or phosphorus atom,
F¹ and F⁵ are, independently of one another, an aryl, heteroaryl, cycloalkyl or heterocycloalkyl group,
F² to F⁴ and F⁶ are, independently of one another, a heteroaryl group containing N and/or P as hetero ring atom,
R a C₁-C₄₀-hydrocarbon radical,
R¹, R², R⁵ and R⁶ are, independently of one another, hydrogen or a C₁-C₄₀-hydrocarbon radical if they are bonded to a nitrogen atom,
R¹, R², R⁵ and R⁶ are, independently of one another, a C₁-C₄₀-hydrocarbon radical if they are bonded to a phosphorus atom and
R³ and R⁴ are, independently of one another, hydrogen, halogen or a C₁-C₄₀-hydrocarbon radical, where n=an integer between 1 and 5.

22. The device according to claim 18, wherein the C₁- to C₄₀-hydrocarbon is an alkyl, cycloalkyl, alkenyl, cycloalkenyl, alkynyl, cycloalkynyl, alkylcycloalkyl, heteroalkyl, heterocycloalkyl, heteroalkylcycloalkyl, aryl, heteroaryl, aralkyl or heteroaralkyl group.

23. The device according to claim 16, wherein M¹ and M² are, independently of one another, Cu, Ag, Au, Pd, Pt, Rh, Ir, Re, Os, Mo, W or Zn.

24. The device according to claim 16, wherein the metal complex compound has one of the formulae XIV or XX 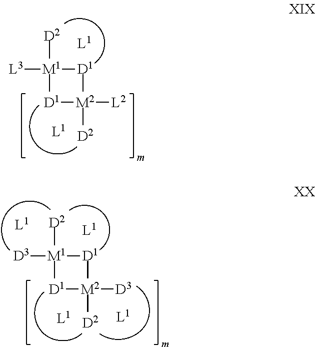
in which
the ligands L¹ containing the donors D¹ and D² as well as D¹ and D² and D³ are defined as in the formulae I to IX,
M¹ and M² are, independently of one another, Cu, Ag, Au, Pd, Pt, Rh, Ir, Re, Os, Mo, W or Zn and
L² and L³ are non-bridging ligands.

25. The device according to claim 16, wherein the metal complex has a ΔE separation between the lowest triplet state and the higher singlet state of between 50 cm⁻¹ and 3000 cm⁻¹.

26. The device according to claim 16, wherein selected from the group consisting of organic electroluminescent device, a light-emitting electrochemical cell, an organic solar cell, an organic field-effect transistor and an organic laser.

27. The device according to claim 16, wherein the device comprises the metal complex as constituent of an emitter layer, where the proportion of the metal complex in the emitter layer is between 0.1 and 50% by weight.

28. The device according to claim 16, wherein the device comprises the metal complex as constituent of an absorber layer, where the proportion of the metal complex in the absorber layer is between 30 and 100% by weight.

29. A process for the generation of light of a certain wavelength, comprising the step of proving a polynuclear metal complex compound having a first metallic centre M¹ and a second metallic centre M² and a polydentate, asymmetrical ligand L¹, which contains a phosphido or amido donor D¹ bridging the first and second metallic centres M¹ and M², and a further donor D², which is bonded either to the first or to the second metallic centre.

30. A process for the generation of blue emission which comprises utilizing a polynuclear metal complex compound having a first metallic centre M¹ and a second metallic centre M² and a polydentate, asymmetrical ligand L¹, which contains a phosphido or amido donor D¹ bridging the first and second metallic centres M¹ and M², and a further donor D², which is bonded either to the first or to the second metallic centre.

31. A process for the production of the electronic device according to claim 16, comprising bonding
a polynuclear metal complex compound having a first metallic centre M¹ and a second metallic centre M² and a polydentate, asymmetrical ligand L¹, which contains a phosphido or amido donor D¹ bridging the first and second metallic centres M¹ and M²,
a further donor D², either to the first or to the second metallic centre, and printing onto a substrate.
